(19) United States
(12) Patent Application Publication
(10) Pub. No.: US 2026/0282671 A1
(43) Pub. Date: Sep. 17, 2026

(54) DISPLAY DEVICE AND MANUFACTURING METHOD OF THE SAME

(71) Applicant: Magnolia White Corporation, Tokyo (JP)

(72) Inventors: Tomokazu ISHIKAWA, Tokyo (JP); Hideyuki TAKAHASHI, Tokyo (JP); Sho YANAGISAWA, Tokyo (JP); Ryota TAKASAKI, Tokyo (JP)

(73) Assignee: Magnolia White Corporation, Tokyo (JP)

(21) Appl. No.: 19/563,159

(22) Filed: Mar. 11, 2026

(30) Foreign Application Priority Data
Mar. 12, 2025 (JP) 2025-038856

(51) Int. Cl. H10K 59/124; H10K 59/12; H10K 59/122; H10K 59/131; H10K 59/80

(52) U.S. Cl. CPC H10K 59/124; H10K 59/1201; H10K 59/122; H10K 59/131; H10K 59/871; H10K 59/874

(57) ABSTRACT

According to one embodiment, a display device includes a substrate, a circuit layer including conductive layers and inorganic insulating layers that constitute a pixel circuit, a first organic insulating layer above the circuit layer, a rib layer above the first organic insulating layer and having a pixel aperture, a display element overlapping the pixel aperture, and a partition above the rib layer and having an overhang shape surrounding the display element. Further, a first area is formed along an end portion of the substrate, and at least one of the plurality of inorganic insulating layers are removed in the first area.

### CROSS-REFERENCE TO RELATED APPLICATION

This application is based upon and claims the benefit of priority from Japanese Patent Application No. 2025-038856, filed Mar. 12, 2025, the entire contents of which are incorporated herein by reference.

### FIELD

Embodiments described herein relate generally to a display device and a manufacturing method of the same.

### BACKGROUND

Recently, display devices with organic light-emitting diodes (OLED) applied thereto as display elements have been put into practical use. This type of display devices demand a technique for improving the yield.

### BRIEF DESCRIPTION OF THE DRAWINGS

FIG. 1 is a view showing a configuration example of a display device according to the first embodiment.

FIG. 2 is a schematic plan view showing an example of the layout of subpixels.

FIG. 3 is a schematic cross-sectional view of a display panel along the III-III line of FIG. 2.

FIG. 4 is a schematic plan view of the display device according to the first embodiment.

FIG. 5 is a schematic cross-sectional view of a configuration applicable to a part surrounded by the broken-line frame V in FIG. 4.

FIG. 6 is a view showing an example of the configuration of an inorganic insulating layer included in a circuit layer.

FIG. 7 is a schematic plan view of a configuration applicable to a part surrounded by the broken-line frame VII in FIG. 4.

FIG. 8 is a schematic cross-sectional view of the display device along the VIII-VIII line of FIG. 7.

FIG. 9 is a schematic cross-sectional view of the display device along the IX-IX line of FIG. 7.

FIG. 10 is a schematic plan view of a mother substrate according to the first embodiment.

FIG. 11 is a flowchart showing an example of a manufacturing method of the display device according to the first embodiment.

FIG. 12A is a schematic cross-sectional view showing a manufacturing process of the display device according to the first embodiment.

FIG. 12B is a schematic cross-sectional view showing a process following the process shown in FIG. 12A.

FIG. 12C is a schematic cross-sectional view showing a process following the process shown in FIG. 12B.

FIG. 12D is a schematic cross-sectional view showing a process following the process shown in FIG. 12C.

FIG. 12E is a schematic cross-sectional view showing a process following the process shown in FIG. 12D.

FIG. 12F is a schematic cross-sectional view showing a process following the process shown in FIG. 12E.

FIG. 12G is a schematic cross-sectional view showing a process following the process shown in FIG. 12F.

FIG. 13A is a schematic cross-sectional view showing a state where a configuration in the vicinity of an end portion of a substrate is formed.

FIG. 13B is a schematic cross-sectional view showing a process following the process shown in FIG. 13A.

FIG. 13C is a schematic cross-sectional view showing a process following the process shown in FIG. 13B.

FIG. 13D is a schematic cross-sectional view showing a process following the process shown in FIG. 13C.

FIG. 13E is a schematic cross-sectional view showing a process following the process shown in FIG. 13D.

FIG. 13F is a schematic cross-sectional view showing a process following the process shown in FIG. 13E.

FIG. 14A is a schematic cross-sectional view showing a state where a configuration in the vicinity of a line is formed.

FIG. 14B is a schematic cross-sectional view showing a process following the process shown in FIG. 14A.

FIG. 14C is a schematic cross-sectional view showing a process following the process shown in FIG. 14B.

FIG. 14D is a schematic cross-sectional view showing a process following the process shown in FIG. 14C.

FIG. 14E is a schematic cross-sectional view showing a process following the process shown in FIG. 14D.

FIG. 14F is a schematic cross-sectional view showing a process following the process shown in FIG. 14E.

FIG. 14G is a schematic cross-sectional view showing a process following the process shown in FIG. 14F.

FIG. 15 is a schematic plan view showing the vicinity of a terminal portion before being cut along a cut line.

FIG. 16A is a schematic cross-sectional view showing a manufacturing process of a display device according to the second embodiment.

FIG. 16B is a schematic cross-sectional view showing a process following the process shown in FIG. 16A.

FIG. 16C is a schematic cross-sectional view showing a process following the process shown in FIG. 16B.

FIG. 17A is a schematic cross-sectional view showing a manufacturing process of a display device according to the third embodiment.

FIG. 17B is a schematic cross-sectional view showing a process following the process shown in FIG. 17A.

FIG. 17C is a schematic cross-sectional view showing a process following the process shown in FIG. 17B.

FIG. 18A is a schematic cross-sectional view showing a manufacturing process of the display device according to the fourth embodiment.

FIG. 18B is a schematic cross-sectional view showing a process following the process shown in FIG. 18A.

FIG. 18C is a schematic cross-sectional view showing a process following the process shown in FIG. 18B.

FIG. 18D is a schematic cross-sectional view showing a process following the process shown in FIG. 18C.

FIG. 18E is a schematic cross-sectional view showing a process following the process shown in FIG. 18D.

FIG. 18F is a schematic cross-sectional view of a modified example of the fourth embodiment.

FIG. 19A is a schematic cross-sectional view showing a manufacturing process of a display device according to the fifth embodiment.

FIG. 19B is a schematic cross-sectional view showing a process following the process shown in FIG. 19A.

FIG. 19C is a schematic cross-sectional view showing a process following the process shown in FIG. 19B.

FIG. 20 is a schematic cross-sectional view of a display device according to the sixth embodiment.

FIG. 21 is a schematic cross-sectional view of a display device according to the seventh embodiment.

### DETAILED DESCRIPTION

In general, according to one embodiment, a display device includes a substrate, a circuit layer provided above the substrate and including a plurality of conductive layers and a plurality of inorganic insulating layers that constitute a pixel circuit configured to drive a pixel in a display area, a first organic insulating layer provided above the circuit layer, a rib layer provided above the first organic insulating layer and having a pixel aperture in the pixel, a display element overlapping the pixel aperture, and a partition provided above the rib layer and having an overhang shape surrounding the display element. Further, a first area is formed along an end portion of the substrate, and at least one of the plurality of inorganic insulating layers are removed in the first area.

According to another embodiment, a manufacturing method of a display device includes forming above a substrate a circuit layer including a plurality of conductive layers and a plurality of inorganic insulating layers that constitute a pixel circuit configured to drive a pixel in a display area, removing at least one of the plurality of inorganic insulating layers in a first area along a cut line for cutting out a panel portion including the display area from the substrate, forming a first organic insulating layer above the circuit layer, forming a rib layer provided above the first organic insulating layer and having a pixel aperture in the pixel, forming above the rib layer a partition having an overhang shape surrounding the pixel aperture, forming a display element overlapping the pixel aperture, and cutting the substrate along the cut line.

For example, embodiments can improve yield of the display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

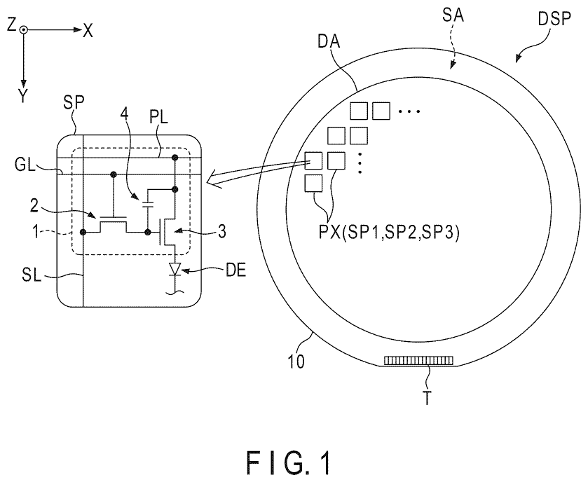

FIG. 1 is a view showing a configuration example of a display device DSP of the first embodiment. The display device DSP comprises an insulating substrate 10. The substrate 10 has a display area DA for displaying images and a surrounding area SA around the display area DA. The substrate 10 may be glass or a resinous film having flexibility.

In the present embodiment, the substrate 10 and the display area DA have a circular shape in plan view. The shape of each of the substrate 10 and the display area DA in plan view is not limited to a circular shape and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP that display mutually different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T to which signals and voltages for driving the subpixels SP1, SP2, and SP3 are input. The terminal portion T is provided in the surrounding area SA. For example, a flexible printed circuit board, which applies the voltages and signals, is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A plurality of scanning lines GL applying a scanning signal to the pixel circuit 1 of each subpixel SP, a plurality of signal lines SL applying a video signal to the pixel circuit 1 of each subpixel SP, and a plurality of power lines PL are provided in the display area DA. In the example of FIG. 1, the scanning lines GL and the power lines PL extend in the X-direction, and the signal lines SL extend in the Y-direction.

A gate electrode of the pixel switch 2 is connected to the scanning line GL. One of a source electrode and a drain electrode of the pixel switch 2 is connected to the signal line SL. The other is connected to a gate electrode of the drive transistor 3 and the capacitor 4. In the drive transistor 3, one of a source electrode and a drain electrode is connected to the power line PL and the capacitor 4. The other is connected to the display element DE.

The configuration of the pixel circuit 1 is not limited to the illustrated example. For example, the pixel circuit 1 may comprise more thin-film transistors and capacitors.

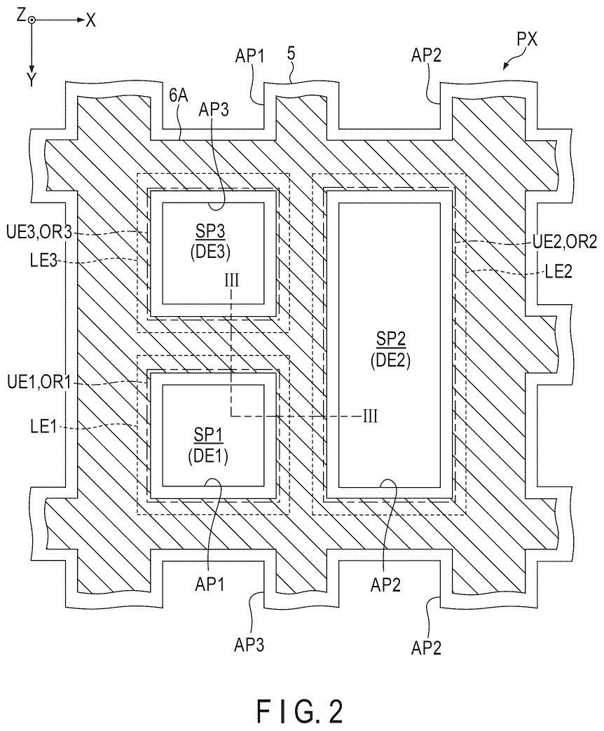

FIG. 2 is a schematic plan view showing an example of the layout of the subpixels SP1, SP2, and SP3 constituting one pixel PX. In the example of FIG. 2, the subpixels SP1 and SP3 are arranged in the Y-direction. Each of the subpixels SP1 and SP3 is adjacent to the subpixel SP2 in the X-direction.

When the subpixels SP1, SP2, and SP3 are arranged in this layout, in the display area DA, a column in which the subpixels SP1 and SP3 are alternately arranged in the Y-direction and a column in which the plurality of subpixels SP2 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 in the respective subpixels SP1, SP2, and SP3. In the example of FIG. 2, the pixel apertures AP1 and AP3 are rectangles having the same planar size. In contrast, the pixel aperture AP2 is a rectangle extending longer in the Y-direction than the pixel apertures AP1 and AP3. The shapes of the pixel aperture AP1, AP2, and AP3 are not limited to this example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

Parts overlapping the pixel aperture AP1 of the lower electrode LE1, the upper electrode UE1, and the organic layer OR1 constitute a display element DE1 of the subpixel SP1. Parts overlapping the pixel aperture AP2 of the lower electrode LE2, the upper electrode UE2, and the organic layer OR2 constitute a display element DE2 of the subpixel SP2. Parts overlapping the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6A (the first partition) is provided above the rib layer 5. The partition 6A functions as lines that apply common voltage to the upper electrodes UE1, UE2, and UE3. The partition 6A entirely overlaps the rib layer 5 and has the same planar shape as that of the rib layer 5. Further, the partition 6A surrounds each of the pixel apertures AP1, AP2, and AP3.

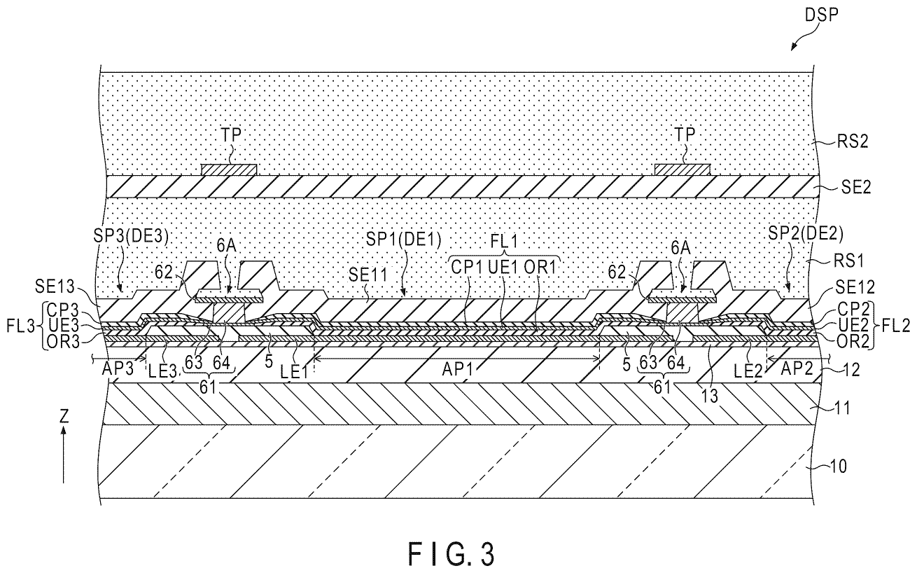

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered with an organic insulating layer 12 (the first organic insulating layer). The organic insulating layer 12 functions as a planarization film, which planarizes irregularities formed by the circuit layer 11.

The organic insulating layer 12 is covered with a waterproof layer 13. The waterproof layer 13 suppresses infiltration of moisture from the organic insulating layer 12 into the display elements DE1, DE2, and DE3.

The lower electrodes LE1, LE2, and LE3 are provided on the waterproof layer 13. The rib layer 5 is provided on the organic insulating layer 12 and the lower electrodes LE1, LE2, and LE3. End portions of the lower electrodes LE1, LE2, and LE3 are covered with the rib layer 5. Although not shown in the cross section of FIG. 3, the lower electrodes LE1, LE2, and LE3 are connected to the respective pixel circuits 1 of the circuit layer 11 through respective contact holes provided in the organic insulating layer 12 and the waterproof layer 13.

The partition 6A includes a conductive lower portion 61 provided on the rib layer 5 and an upper portion 62 provided on the lower portion 61. The upper portion 62 has a width greater than that of the lower portion 61. That is, the partition 6A has an overhang shape in which both end portions of the upper portion 62 protrude relative to the side surfaces of the lower portion 61.

In the example of FIG. 3, the lower portion 61 has a bottom layer 63 provided on the rib layer 5, and a stem layer 64 provided on the bottom layer 63. For example, the bottom layer 63 is formed to be thinner than the stem layer 64. In the example of FIG. 3, both end portions of the bottom layer 63 protrude relative to the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portions 61 of the partition 6A.

The display element DE1 has a cap layer CP1 covering the upper electrode UE1. The display element DE2 has a cap layer CP2 covering the upper electrode UE2. The display element DE3 has a cap layer CP3 covering the upper electrode UE3. The cap layers CP1, CP2, and CP3 function as optical adjustment layers which improve the extraction efficiency of the light emitted from the respective organic layers OR1, OR2, and OR3.

In the following explanation, a multilayer body having the organic layer OR1, the upper electrode UE1, and the cap layer CP1 is called a stacked film FL1. A multilayer body having the organic layer OR2, the upper electrode UE2, and the cap layer CP2 is called a stacked film FL2. A multilayer body having the organic layer OR3, the upper electrode UE3, and the cap layer CP3 is called a stacked film FL3.

Sealing layers SE11, SE12, and SE13 are provided in the respective subpixels SP1, SP2, and SP3. The sealing layer SE11 continuously covers the display element DE1 and the partition 6A around the display element DE1. The sealing layer SE12 continuously covers the display element DE2 and the partition 6A around the display element DE2. The sealing layer SE13 continuously covers the display element DE3 and the partition 6A around the display element DE3.

In the example of FIG. 3, the sealing layer SE11 located on the partition 6A between the subpixels SP1 and SP2 is spaced apart from the sealing layer SE12 located on this partition 6A. The sealing layer SE11 located on the partition 6A between the subpixels SP1 and SP3 is spaced apart from the sealing layer SE13 located on this partition 6A. Among the sealing layers SE11, SE12, and SE13, adjacent two sealing layers may overlap each other in the Z-direction above the partition 6A.

For example, gaps are formed between the respective sealing layers SE11, SE12, and SE13 and the upper portion 62 of the partition 6A. The stacked films FL1, FL2, and FL3 may be provided in at least part of these gaps.

The sealing layers SE11, SE12, and SE13 are covered with a resin layer RS1 (the first resin layer). The resin layer RS1 is covered with the sealing layer SE2. The sealing layer SE2 is covered with a resin layer RS2 (the second resin layer). The resin layers RS1 and RS2 and the sealing layer SE2 are continuously provided in at least the entire display area DA and partly extend in the surrounding area SA as well.

In the example of FIG. 3, a touch panel electrode TP for detecting touch operations by a user is provided on the sealing layer SE2 and is covered with the resin layer RS2. For example, the touch panel electrode TP is formed of a metal material and has the same shape as that of the partition 6A in plan view.

A cover member such as a polarizer, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5, the waterproof layer 13, and the sealing layers SE11, SE12, SE13, and SE2 is formed of an inorganic insulating material such as a silicon nitride (SiNx), a silicon oxide (SiOx), or a silicon oxynitride (SiON). In one example, the rib layer 5 is formed of a silicon oxynitride, and each of the waterproof layer 13 and the sealing layers SE11, SE12, SE13, and SE2 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is formed of a plurality of thin films including a light emitting layer. In one example, the organic layers OR1, OR2, and OR3 have a configuration in which a hole-injection layer, a hole-transport layer, an electron blocking layer, a light emitting layer, a hole blocking layer, an electron-transport layer, and an electron-injection layer are stacked in this order in the Z-direction. The organic layers OR1, OR2, and, OR3 each may have other configurations such as a tandem configuration including a plurality of light emitting layers.

Each of the cap layers CP1, CP2, and CP3 has, for example, a multilayer structure in which a plurality of transparent layers are stacked. These transparent layers could have a layer formed of an inorganic material and a layer formed of an organic material. These transparent layers have refractive indices different from each other. For example, the refractive indices of these transparent layers differ from the refractive indices of the upper electrodes UE1, UE2, and UE3 and the refractive indices of the sealing layers SE11, SE12, and SE13. At least one of the cap layers CP1, CP2, and CP3 may be omitted.

Each of the bottom layer 63 and the stem layer 64 of the partition 6A is formed of a metal material. For the metal material of the bottom layer 63, for example, molybdenum, titanium, a titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material.

For example, the upper portion 62 of the partition 6A includes a lower layer formed of a metal material and an upper layer formed of a conductive oxide. In this case, for the metal material of the lower layer, titanium, a titanium nitride, molybdenum, tungsten, a molybdenum-tungsten alloy, or a molybdenum-niobium alloy may be used. Further, for a conductive oxide of the upper layer, an ITO or an IZO may be used. The upper portion 62 may comprise three or more layers or may consist of a single layer. The upper portion 62 may further include a layer formed of an insulating material.

Common voltage is applied to the partition 6A. This common voltage is applied to each of the upper electrodes UE1, UE2, and UE3 that contact the lower portions 61. Pixel voltages according to the video signals of the signal lines SL are applied to the lower electrodes LE1, LE2, and LE3 through the respective pixel circuits 1 provided in the subpixels SP1, SP2, and SP3.

The organic layers OR1, OR2, and OR3 emit light in response to the application of a voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light of the same color (for example, white). In this case, the display device DSP may comprise a color filter that converts light emitted from the light emitting layers into light of the colors corresponding to those of the subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

FIG. 4 is a schematic plan view of the display device DSP. A dam structure DS surrounding the display area DA is provided in the surrounding area SA. In the manufacturing of the display device DSP, the dam structure DS retains the resin layers RS1 and RS2 before curing (refer to FIG. 2).

In the present embodiment, the dam structure DS comprises four dam portions DM (DM1, DM2, DM3, and DM4). The dam portion DM1 surrounds the display area DA. The dam portion DM2 surrounds the dam portion DM1. The dam portion DM3 surrounds the dam portion DM2. The dam portion DM4 surrounds the dam portion DM3. The number of dam portions DM that the dam structure DS comprises is not limited to four.

In the example of FIG. 4, most parts of the dam portions DM1, DM2, DM3, and DM4 have arc shapes along the outer shape of the substrate 10. In the area in the vicinity of the terminal portion T, the dam portions DM1, DM2, DM3, and DM4 extend linearly between the display area DA and the terminal portion T.

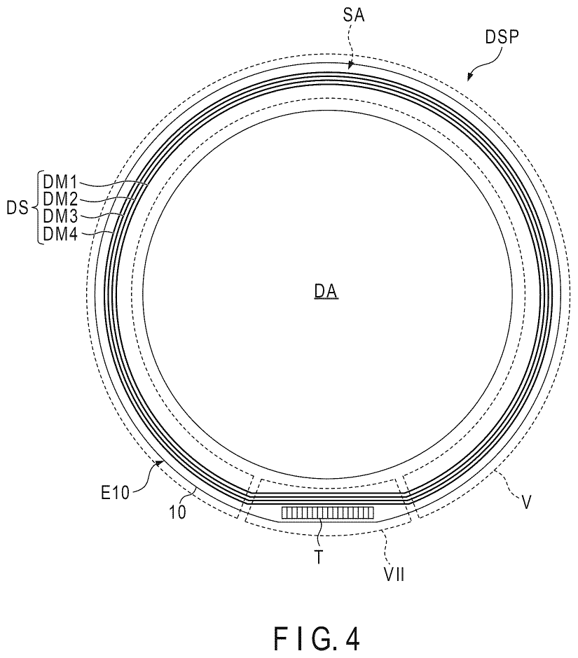

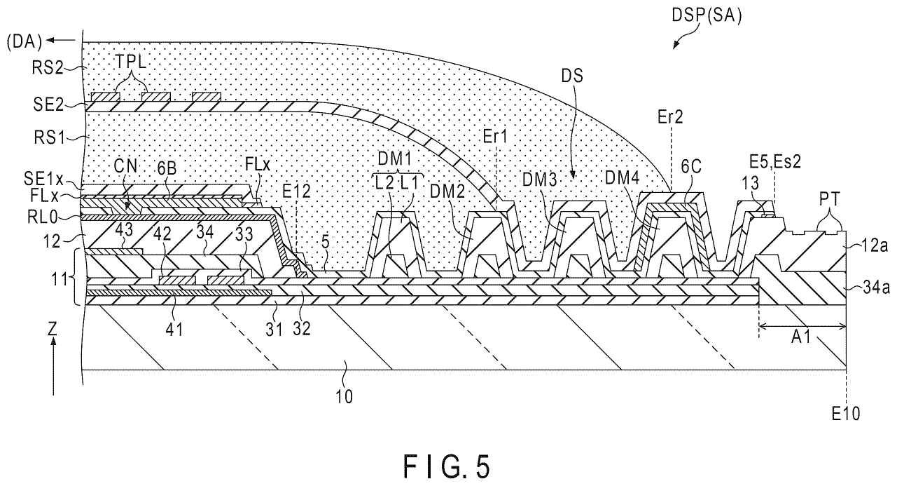

FIG. 5 is a schematic cross-sectional view of a configuration applicable to a part surrounded by the broken-line frame V of the surrounding area SA in FIG. 4. The circuit layer 11 shown in FIG. 3 includes a plurality of conductive layers (such as metal layers and semiconductor layers) and a plurality of insulating layers for constituting circuits such as the pixel circuits 1 and various lines.

FIG. 5 shows inorganic insulating layers 31, 32, and 33 and an organic insulating layer 34 (the second organic insulating layer) as examples of the plurality of insulating layers. Further, FIG. 5 shows metal layers 41, 42, and 43 as examples of the plurality of conductive layers. The inorganic insulating layer 31 covers the upper surface of the substrate 10. The metal layer 41 is provided on the inorganic insulating layer 31. The inorganic insulating layer 32 covers the metal layer 41. The metal layer 42 is provided on the inorganic insulating layer 32. The inorganic insulating layer 33 covers the metal layer 42. The organic insulating layer 34 covers the inorganic insulating layer 33. The metal layer 43 is provided on the organic insulating layer 34 and is covered with the organic insulating layer 12.

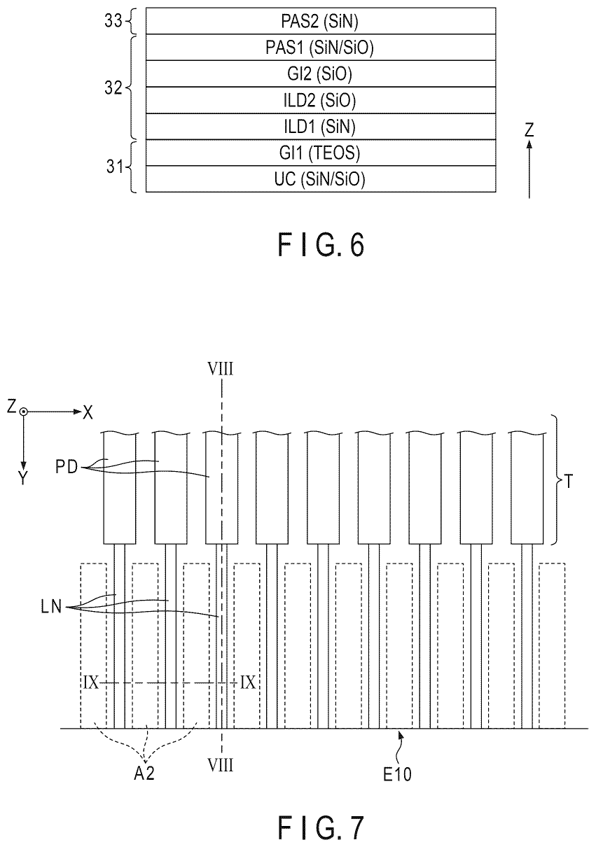

FIG. 6 is a view showing an example of the configuration of inorganic insulating layers 31, 32, and 33 included in a circuit layer. The inorganic insulating layers 31, 32, and 33 may have a multilayer structure in which a plurality of insulating layers are stacked, instead of a single layer structure shown in this figure.

That is, in the example shown in FIG. 6, the inorganic insulating layer 31 has a configuration in which an undercoat film UC formed of a silicon nitride or a silicon oxide and a gate insulating film GI1 formed of TEOS (tetraethoxysilane), which is a type of a silicon oxide, are stacked in the Z-direction. The inorganic insulating layer 32 has a configuration in which an interlayer insulating film ILD1 formed of a silicon nitride, an interlayer insulating film ILD2 formed of a silicon oxide, a gate insulating film GI2 formed of a silicon oxide, and a passivation film PAS1 formed of a silicon nitride or a silicon oxide are stacked in the Z-direction. Further, the inorganic insulating layer 33 is constituted by a passivation film PAS2 formed of a silicon nitride.

In the same manner as the organic insulating layer 12, the organic insulating layer 34 is formed of an organic insulating material such as a polyimide. In addition to these examples, various configurations are applicable to the inorganic insulating layers 31, 32, and 33 and the circuit layer 11.

The inorganic insulating layers 31, 32, and 33 are formed substantially over the entire display area DA and surrounding area SA while having contact holes at various locations such as the pixel circuits 1 and circuits provided in the surrounding area SA. As shown in FIG. 5, a first area A1, in which the inorganic insulating layers 31, 32, and 33 are removed, is formed in the vicinity of an end portion E10 of the substrate 10.

The dam portions DM1, DM2, DM3, and DM4 of the dam structure DS are provided on the inorganic insulating layer 33. For example, the dam portions DM1, DM2, DM3, and DM4 have a stacked layer structure including a first layer L1 and a second layer L2 each formed of an organic insulating material. In this stacked layer structure, the first layer L1 can be formed using the same process and the same material as those of the organic insulating layer 12. Further, the second layer L2 can be formed using the same process and the same material as those of the organic insulating layer 34.

An end portion E12 of the organic insulating layer 12 is closer to the display area DA side than the dam portion DM1. In the example of FIG. 5, a relay layer RL0 is provided on the organic insulating layer 12. For example, the relay layer RL0 is formed of the same process and the same material as those of the lower electrodes LE1, LE2, and LE3.

The relay layer RL0 is covered with the rib layer 5. Further, a partition 6B is provided on the rib layer 5. In the same manner as the partition 6A shown in FIG. 3 and the like, the partition 6B comprises the lower portion 61 (the bottom layer 63 and the stem layer 64) and the upper portion 62. The end portion of the partition 6B has an overhang shape in which the upper portion 62 protrudes relative to the side surface of the lower portion 61.

The partition 6B is connected to the partition 6A. The partition 6B contacts the relay layer RL0 through a contact aperture CN provided in the rib layer 5. Though not shown in the cross section of FIG. 5, the relay layer RL0 is connected to a power line of common voltage.

A stacked film FLx is provided on the partition 6B. The partition 6B and the stacked film FLx are covered with a sealing layer SE1x. In the example of FIG. 5, the end portion of the sealing layer SE1x is located around the partition 6B. The stacked film FLx is provided between the end portion of the sealing layer SE1x and the rib layer 5. In another example, a gap in which the stacked film FLx is not provided may be formed between the end portion of the sealing layer SE1x and the rib layer 5. The stacked film FLx is formed by the same process and the same material as those of any of the stacked films FL1, FL2, and FL3 shown in FIG. 3. The sealing layer SE1x is formed by the same process and the same material as those of any of the sealing layers SE11, SE12, and SE13 shown in FIG. 3. In one example, the stacked film FLx and the sealing layer SE1x are respectively formed as the same process and the same material as those of the stacked film FL3 and the sealing layer SE13. In this case, the stacked film FLx includes the upper electrode UE3, the organic layer OR3, and the cap layer CP3.

The rib layer 5 covers the dam portions DM1, DM2, DM3, and DM4. The rib layer 5 contacts the inorganic insulating layer 33 in the area between the end portion E12 of the organic insulating layer 12 and the dam portion DM1, between the area between the dam portions DM1 and DM2, and the area between the dam portions DM2 and DM3.

In the example of FIG. 5, a partition 6C is provided on the rib layer 5 covering the dam portion DM4. In the same manner as the partitions 6A and 6B, the partition 6C comprises the lower portion 61 (the bottom layer 63 and the stem layer 64) and the upper portion 62. The end portion of the partition 6C has an overhang shape in which the upper portion 62 protrudes relative to the side surface of the lower portion 61.

For example, an end portion Er1 of the resin layer RS1 is located above the dam portion DM2. That is, the resin layer RS1 covers part of the dam portions DM1 and DM2. The position of the end portion Er1 is not limited to this example.

The sealing layer SE2 covers the resin layer RS1 and the dam portions DM2, DM3, and DM4. The sealing layer SE2 contacts the rib layer 5 in an area located outside the end portion Er1 (the right side in the figure). Further, a touch panel line TPL connected to the touch panel electrode TP shown in FIG. 3 is provided on the sealing layer SE2. For example, the touch panel line TPL is formed of the same process and the same material as those of the touch panel electrode TP.

The resin layer RS2 covers the touch panel line TPL and the sealing layer SE2. In the example of FIG. 5, an end portion Er2 of the resin layer RS2 is located above the dam portion DM4. From another view point, the end portion Er2 is located between the end portion Er1 of the resin layer RS1 and the first area A1. The resin layer RS2 covers part of the dam portions DM3 and DM4. The position of the end portion Er2 is not limited to this example.

The first area A1 is continuously formed along the end portion E10 of the substrate 10 in, for example, the area surrounded by the broken-line frame V in FIG. 4. That is, the first area A1 is located outside the dam structure DS. The organic insulating layers 12 and 34 are formed in the first area A1. The following descriptions refer to the organic insulating layers 12 and 34 of the first area A1 as organic insulating layers 12a and 34a, respectively.

The organic insulating layer 12a contacts the upper surface of the organic insulating layer 34a. The organic insulating layer 34a contacts the upper surface of the substrate 10 in the first area A1. In the example of FIG. 5, the upper surface of the organic insulating layer 12a has at least one protrusion portion PT.

The rib layer 5 and the sealing layer SE2 are preferably removed in at least part of the first area A1. In the example of FIG. 5, an end portion E5 of the rib layer 5 and an end portion Es2 of the sealing layer SE2 align. Further, the end portions E5 and Es2 are provided above the organic insulating layer 12a.

In the example of FIG. 5, the waterproof layer 13 shown in FIG. 3 is provided on the organic insulating layer 12a. The waterproof layer 13 covers part of the upper surface of the organic insulating layer 12a and is covered with the rib layer 5.

FIG. 7 is a schematic plan view of a configuration applicable to a part surrounded by the broken-line frame VII of the surrounding area SA in FIG. 4. The following descriptions focus attention on the area between the end portion E10 of the substrate 10 and the terminal portion T.

The terminal portion T comprises a plurality of pads PD extending longer in the Y-direction. These pads PD are arranged in the X-direction with an interval. A plurality of lines LN are provided between the terminal portion T and the end portion E10 of the substrate 10. Each of the lines LN is connected to the pad PD and extends toward the end portion E10 in the Y-direction.

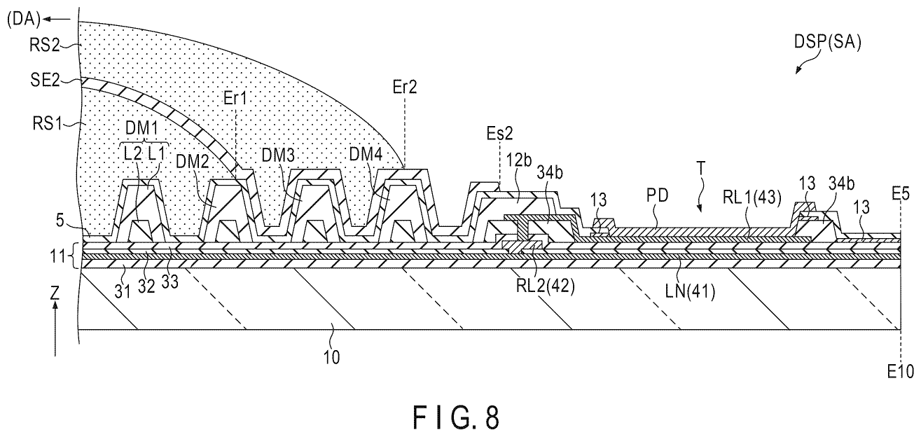

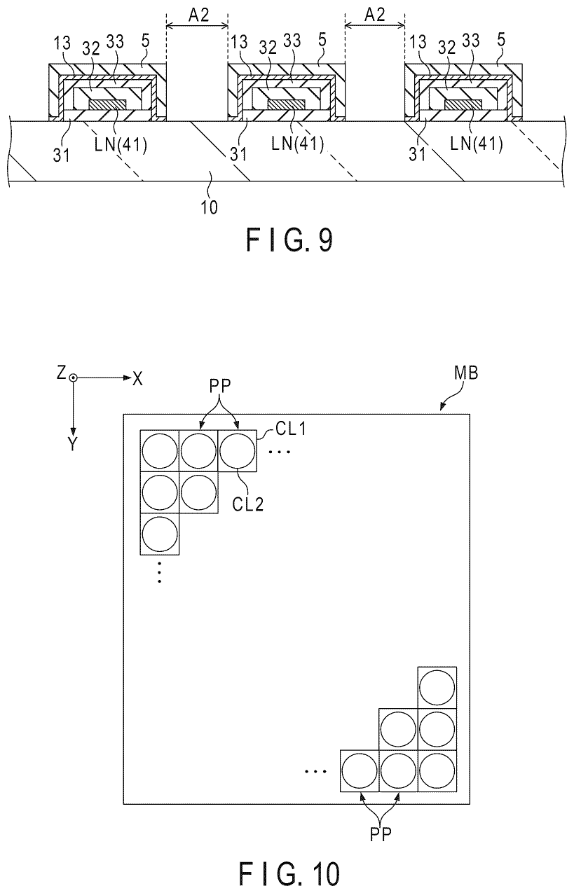

FIG. 8 is a schematic cross-sectional view of the display device DSP along the VIII-VIII line of FIG. 7. FIG. 9 is a schematic cross-sectional view of the display device DSP along the IX-IX line of FIG. 7.

The line LN is formed of any one of the plurality of conductive layers of the circuit layer 11. The present embodiment assumes the case where the line LN is formed of the metal layer 41. As shown in FIG. 8, the line LN extends toward the display area DA while passing below the pad PD.

As shown in FIG. 8 and FIG. 9, the inorganic insulating layer 31 is provided below the line LN. Further, the entire line LN is covered with the inorganic insulating layers 32 and 33.

For example, each pad PD is formed using the same process and the same material as those of the touch panel electrode TP. The pad PD contacts the relay layer RL1 provided below the pad PD. The relay layer RL1 is connected to the line LN through a relay layer RL2. For example, the relay layer RL1 is formed of the metal layer 43, and the relay layer RL2 is formed of the metal layer 42.

The organic insulating layers 12 and 34 are provided around the pads PD. The following descriptions refer to these organic insulating layers 12 and 34 as organic insulating layers 12b and 34b, respectively. The organic insulating layer 34b has an aperture at the position overlapping the pad PD. The organic insulating layer 12b is located between the pad PD and the dam portion DM4.

The organic insulating layers 12b and 34b are covered with the rib layer 5. The rib layer 5 has an aperture in the pad PD. In the example of FIG. 8, the waterproof layer 13 is provided below the rib layer 5 at an edge portion of the aperture. The waterproof layer 13 is also provided in the area between the pad PD and the end portion E10 of the substrate 10. The end portion Es2 of the sealing layer SE2 is located between the pad PD and the dam portion DM4.

In the cross section of FIG. 9, the line LN provided above the inorganic insulating layer 31 is covered with the inorganic insulating layers 32 and 33, the waterproof layer 13, and the rib layer 5. In the second area A2 between adjacent lines LN, the inorganic insulating layers 31, 32, and 33, the waterproof layer 13, and the rib layer 5 are removed.

As shown in FIG. 7, the second area A2 extends in the Y-direction between adjacent lines LN. One end of the second area A2 reaches the end portion E10 of the substrate 10. For example, in the second area A2, the upper surface of the substrate 10 is not covered with any of the layers disclosed in the present embodiment.

The following will describe an example of the manufacturing method of the display device DSP. In the manufacturing of the display device DSP, a large mother substrate is fabricated, the mother substrate comprising a plurality of areas (panel portions) each including a portion corresponding to the display device DSP.

FIG. 10 is a schematic plan view of a mother substrate MB (a mother substrate for a display device) according to the present embodiment. For example, the mother substrate MB has a rectangular shape as shown in the figure. However, the mother substrate MB may have another shape such as a circular shape.

The mother substrate MB comprises a plurality of panel portions PP provided in a matrix. In the example of FIG. 10, the panel portions PP are arranged in the X-direction and the Y-direction without margins. The layout of the panel portions PP in the mother substrate MB is not limited to this example. Alternatively, margins may be provided between the panel portions PP that are adjacent to each other in the X-direction or the Y-direction.

The outer shape of the panel portion PP corresponds to a cut line CL1 for cutting out the panel portion PP from the mother substrate MB. Each panel portion PP further has a cut line CL2 corresponding to the outer shape of the display device DSP.

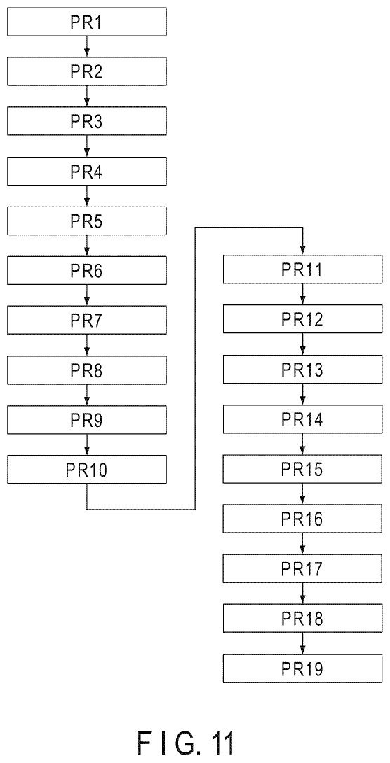

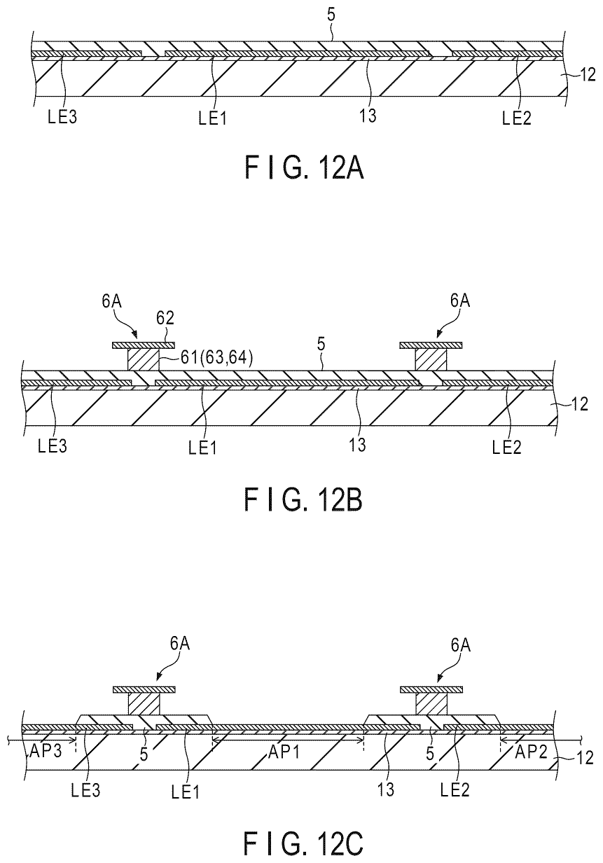

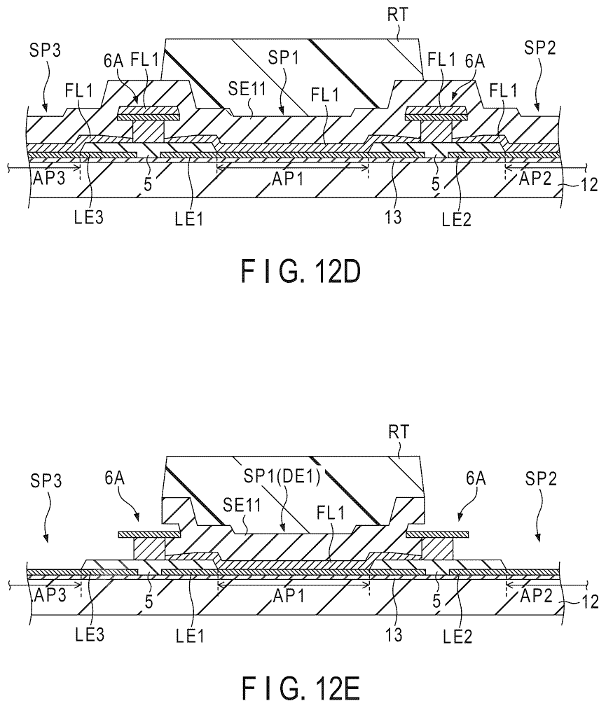

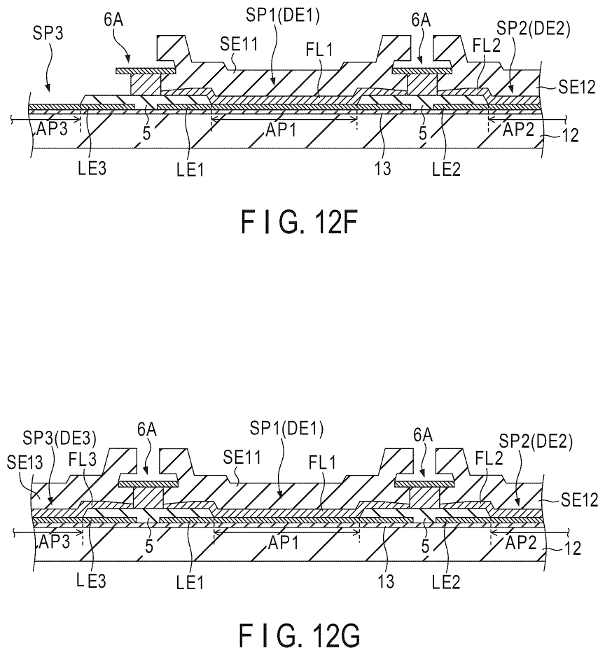

FIG. 11 is a flowchart showing an example of the manufacturing method of the display device DSP. FIG. 12A to FIG. 12G are schematic cross-sectional views showing the manufacturing process of the display device DSP. FIG. 12A to FIG. 12G mainly focus on the display area DA and omit the illustration of elements under the organic insulating layer 12.

In the formation of the panel portion PP, first, the circuit layer 11 including the inorganic insulating layers 31, 32, and 33, the organic insulating layer 34, the metal layers 41, 42, and 43, and the like is formed above the substrate 10 of the mother substrate MB (the process PR1 in FIG. 11). Further, the organic insulating layer 12 covering the circuit layer 11 is formed (the process PR2 in FIG. 11). At this time, the dam portions DM1, DM2, DM3, and DM4 are formed as well.

After the process PR2, the waterproof layer 13 is formed on the organic insulating layer 12 as shown in FIG. 12A (the process PR3 in FIG. 11). Next, the lower electrodes LE1, LE2, and LE3 are formed above the waterproof layer 13 (the process PR4 in FIG. 11). Thereafter, the rib layer 5 covering the lower electrodes LE1, LE2, and LE3 is formed on the entire mother substrate MB (the process PR5 in FIG. 11). At this time, the pixel apertures AP1, AP2, and AP3 are not provided in the rib layer 5. The waterproof layer 13 and the rib layer 5 can be formed by chemical vapor deposition (CVD).

After the formation of the rib layer 5, the partition 6A is formed on the rib layer 5 as shown in FIG. 12B (the process PR6 in FIG. 11). The partitions 6B and 6C of the surrounding area SA are formed together with the partition 6A.

Next, the pixel apertures AP1, AP2, and AP3 are formed in the rib layer 5 as shown in FIG. 12C (the process PR7 in FIG. 11). The pixel apertures AP1, AP2, and AP3 may be formed prior to the formation of the partitions 6A, 6B, and 6C.

After the process PR7, the process for forming the display element DE1 is performed (the process PR8 in FIG. 11). In the formation of the display element DE1, the stacked film FL1 and the sealing layer SE11 are formed first as shown in FIG. 12D. As shown in FIG. 3, the stacked film FL1 has the organic layer OR1 contacting the lower electrode LE1 through the pixel aperture AP1, the upper electrode UE1 covering the organic layer OR1, and the cap layer CP1 covering the upper electrode UE1. For example, the organic layer OR1, the upper electrode UE1, and the cap layer CP1 may be formed by vapor deposition. For example, the sealing layer SE11 may be formed by CVD.

The stacked film FL1 and the sealing layer SE11 are formed on the entire mother substrate MB including the surrounding area SA as well as the display area DA of each panel portion PP. The stacked film FL1 is divided by the partitions 6A, 6B, and 6C having overhang shapes. The sealing layer SE11 continuously covers the parts into which the stacked film FL1 is divided, and the partitions 6A, 6B, and 6C.

Subsequently, the stacked film FL1 and the sealing layer SE11 are patterned. In this patterning, a resist RT is provided on the sealing layer SE11 as shown in FIG. 12D. The resist RT covers the subpixel SP1 and part of the partition 6A around the subpixel SP1.

Subsequently, an etching process using the resist RT as a mask is performed. As shown in FIG. 12E, this etching process removes parts exposed from the resist RT of the stacked film FL1 and the sealing layer SE11. That is, parts overlapping the lower electrode LE1 of the stacked film FL1 and the sealing layer SE11 remain. The other parts of the stacked film FL1 and the sealing layer SE11 are removed. These processes form the display element DE1 in the subpixel SP1. For example, this etching process removes the stacked film FL1 and the sealing layer SE11 in the parts other than the display area DA. This etching process may include wet etching and dry etching performed in order on the sealing layer SE11, the cap layer CP1, the upper electrode UE1, and the organic layer OR1. After these etching processes, the resist RT is removed (stripped).

After the process PR8, the process for forming the display element DE2 is performed (the process PR9 in FIG. 11). The display element DE2 can be formed by the same procedure as that of the display element DE1. That is, in the formation of the display element DE2, the stacked film FL2 and the sealing layer SE12 are formed on the entire mother substrate MB. The stacked film FL2 includes the organic layer OR2 contacting the lower electrode LE2 through the pixel aperture AP2, the upper electrode UE2 covering the organic layer OR2, and the cap layer CP2 covering the upper electrode UE2 as shown in FIG. 3.

The organic layer OR2, the upper electrode UE2, and the cap layer CP2 may be formed by, for example, vapor deposition. The sealing layer SE12 may be formed by, for example, CVD. Patterning these stacked film FL2 and sealing layer SE2 forms the display element DE2 in the subpixel SP2 as shown in FIG. 12F. For example, the etching in the patterning removes the stacked film FL2 and the sealing layer SE12 in the parts other than the display area DA.

After the process PR9, the process for forming the display element DE3 is performed (the process PR10 in FIG. 11). The display element DE3 can be formed by the same procedures as those of the display elements DE1 and DE2. That is, in the formation of the display element DE3, the stacked film FL3 and the sealing layer SE13 are formed on the entire mother substrate MB. The stacked film FL3 includes, the organic layer OR3 contacting the lower electrode LE3 through the pixel aperture AP3, the upper electrode UE3 covering the organic layer OR3, and the cap layer CP3 covering the upper electrode UE3 as shown in FIG. 3.

The organic layer OR3, the upper electrode UE3, and the cap layer CP3 may be formed by, for example, vapor deposition. The sealing layer SE13 may be formed by, for example, CVD. Patterning these stacked film FL3 and sealing layer SE13 forms the display element DE3 in the subpixel SP3 as shown in FIG. 12G.

For example, the etching in this patterning removes the stacked film FL3 and the sealing layer SE13 in the most part of the surrounding area SA and margin area BA. Parts covering the partition 6B of the stacked film FL3 and the sealing layer SE13 remain. In this manner, the remaining parts correspond to the stacked film FLx and the sealing layer SE1x.

Here, the above description assumes that the display elements DE1, DE2, and DE3 are formed in this order. However, the display elements DE1, DE2, and DE3 may be formed in another order.

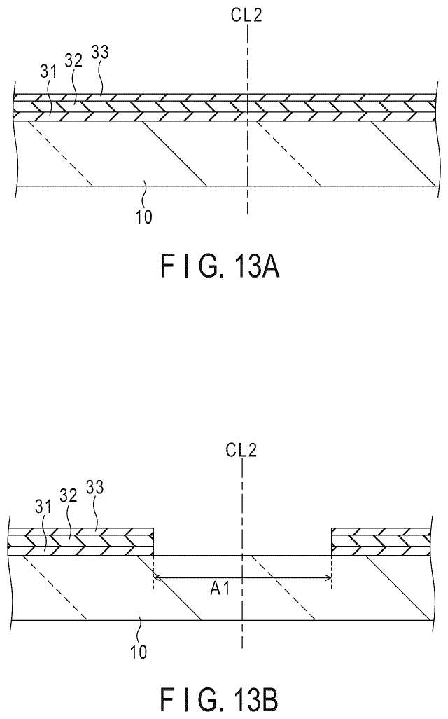

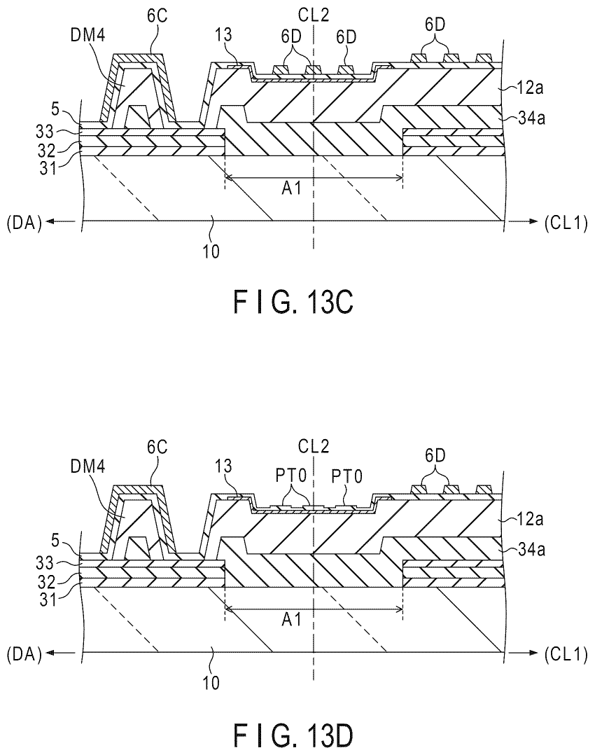

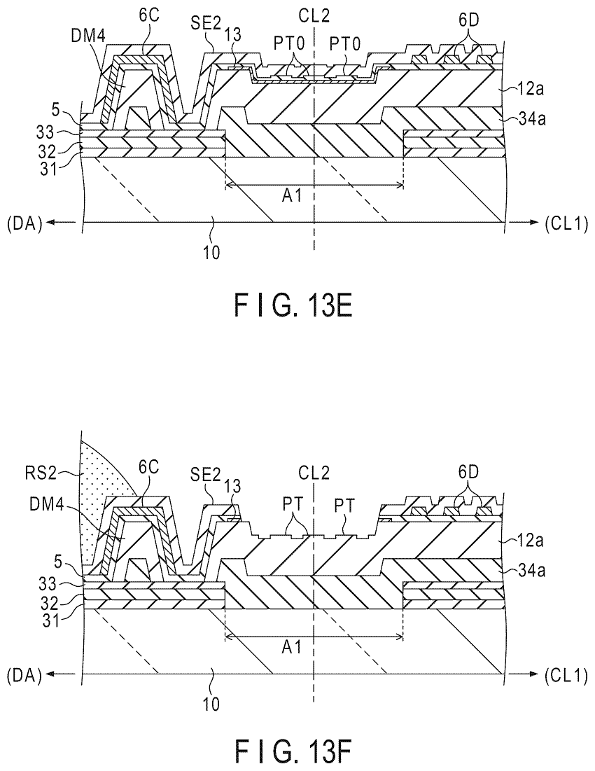

After the process PR10, a part of the partition provided (the partition 6D shown in FIG. 13C) in the surrounding area SA is removed (the process PR11 in FIG. 11). The details of the process PR11 will be described later.

After the process PR11, the resin layer RS1 is formed (the process PR12 in FIG. 11). For example, the resin layer RS1 is formed by an ink-jet method. During this process, uncured materials of the resin layer RS1 are retained by the dam portions DM1 and DM2. After the process PR12, the sealing layer SE2 is formed, for example, by CVD (the process PR13 in FIG. 11).

After the process PR13, etching is performed to remove the rib layer 5 covering the terminal portion T, the waterproof layer 13, and the sealing layer SE2 (the process PR14 in FIG. 11). Further, etching is performed to remove the sealing layer SE2 at a predetermined position in the surrounding area SA (the process PR15 in FIG. 11). The etching in the process PR15 is performed with a strength that hardly erodes the rib layer 5 and the waterproof layer 13. For example, each etching in the processes PR14 and PR15 are dry etching.

After the process PR15, the touch panel electrode TP, the touch panel line TPL, and the pad PD are formed (the process PR16 in FIG. 11). Further, the resin layer RS2 is formed (the process PR17 in FIG. 11). For example, the resin layer RS2 is formed by an ink-jet method. During this process, uncured materials of the resin layer RS2 are retained by the dam portions DM3 and DM4. Even if the dam portions DM3 and DM4 fail to retain the materials at some locations, the materials can be retained by the organic insulating layers 12a and 34a shown in FIG. 5. That is, the organic insulating layers 12a and 34a function as the dam portions as well.

After the process PR17, the mother substrate MB is cut along the cut line CL1 (the process PR18 in FIG. 11). Further, the panel portion PP is cut along the cut line CL2 (the process PR19 in FIG. 11). This completes the display device DSP.

Each cutting in the processes PR18 and PR19 uses laser cut, which applies infrared laser along the cut lines CL1 and CL2. The cutting in at least one of the processes PR18 and PR19 may be other types of cutting such as scribe cut.

Next, the following will describe the formation of the configuration shown in FIG. 5 in the processes PR1 to PR19.

FIG. 13A to FIG. 13F are schematic cross-sectional views showing a state where a configuration in the vicinity of the end portion E10 of the substrate 10 is formed. These figures focus attention on the vicinity of the cut line CL2. The left side of the figure is the display area DA side, and the right side of the figure is the cut line CL1 side. That is, the parts on the left side of the cut line CL2 will be processed into the display device DSP.

As shown in FIG. 13A, the inorganic insulating layers 31, 32, and 33 are formed in the vicinity of the cut line CL2 in the process PR1 for forming the circuit layer 11. Further, etching removes the inorganic insulating layers 31, 32, and 33 in the vicinity of the cut line CL2 as shown in FIG. 13B. These processes form the first area A1. For example, etching on the inorganic insulating layers 31, 32, and 33 is dry etching.

Thereafter, the organic insulating layer 34a is formed as shown in FIG. 13C. Further, the organic insulating layer 12a is formed in the vicinity of the cut line CL2 in the process PR2 for forming the organic insulating layer 12. At this time, the formation of the dam portions DM1, DM2, DM3, and DM4 is completed as well.

In the subsequent processes PR3, PR5, and PR6, the waterproof layer 13, the rib layer 5, and the partition 6C are formed as shown in FIG. 13C. At this time, the waterproof layer 13 overlaps the most part of the first area A1.

In the process PR6, the plurality of partitions 6D may be provided above the organic insulating layer 12a. In the same manner as the partitions 6A, 6B, and 6C, the partition 6D comprises the lower portion 61 (the bottom layer 63 and the stem layer 64) and the upper portion 62. The end portion of the partition 6D has an overhang shape in which the upper portion 62 protrudes relative to the side surface of the lower portion 61.

As shown in FIG. 13D, etching in the process PR11 after the formation of the display elements DE1, DE2, and DE3 removes the partition 6D in the first area A1. This etching may include wet etching or dry etching on each layer of the partition 6D. At the time of these etching processes, the resist protects parts except the first area A1.

The dry etching on the partition 6D may erode the rib layer 5 as well. More specifically, parts not having the partition 6D of the rib layer 5 in the first area A1 are readily eroded. Thus, a protrusion portion PT0 corresponding to the shape of the partition 6D is formed on the surface of the rib layer 5.

In the subsequent process PR13, the sealing layer SE2 is formed in the vicinity of the cut line CL2 as well. This configuration causes the sealing layer SE2 to cover the protrusion portion PT0 and the partition 6D as shown in FIG. 13E.

In the subsequent process PR14, etching is performed to remove at least part of the rib layer 5, the waterproof layer 13, and the sealing layer SE2 in the first area A1. In the example of FIG. 13F, part of the waterproof layer 13 remains on the organic insulating layer 12a. This etching may slightly erode the upper surface of the organic insulating layer 12a as well. Thus, in cases where the protrusion portion PT0 is formed on the rib layer 5, the protrusion portion PT corresponding to the shape of the protrusion portion PT0 is formed on the upper surface of the organic insulating layer 12a.

In the process PR19, the panel portions PP are cut along the cut line CL2. This cutting yields the configuration shown in FIG. 5.

Next, the following will describe the formation of the configuration shown in FIG. 8 and FIG. 9.

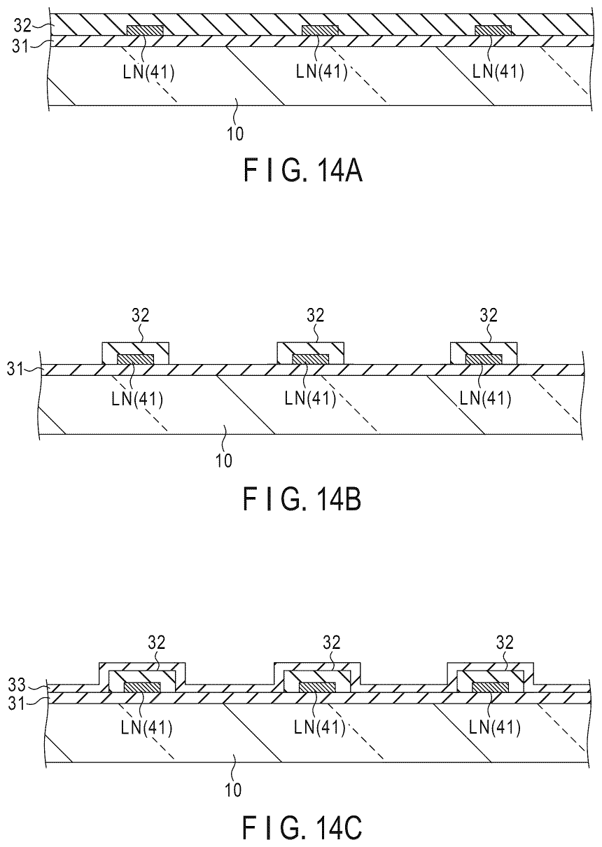

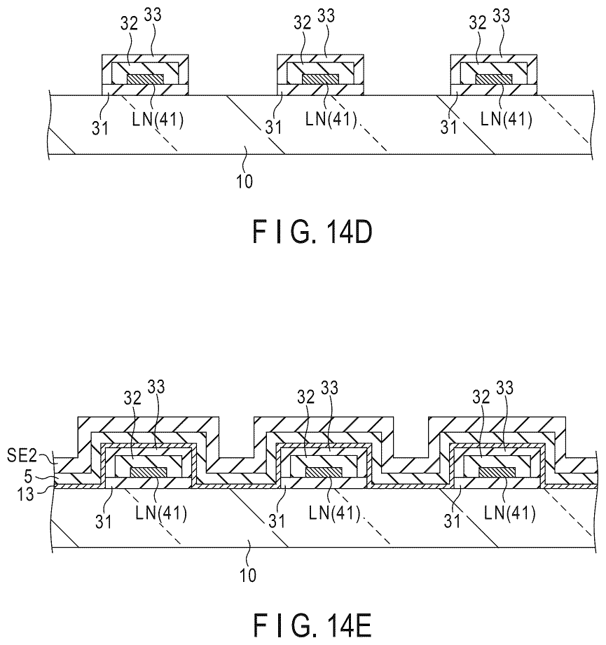

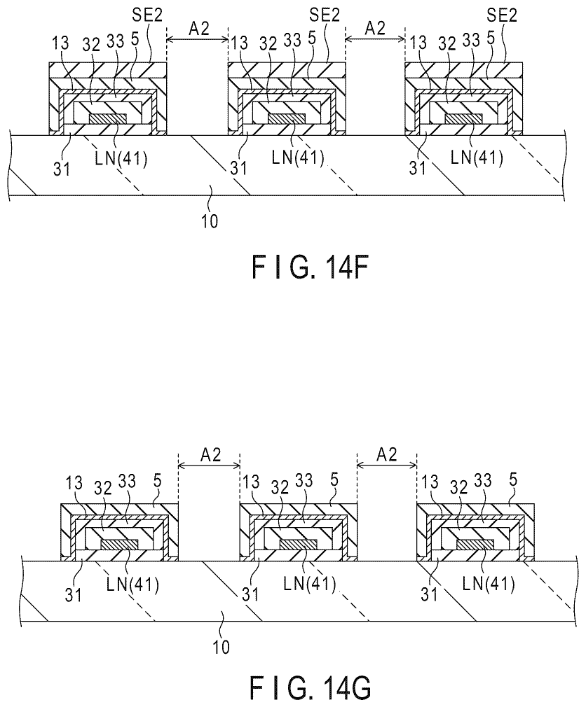

FIG. 14A to FIG. 14G are schematic cross-sectional views showing a state where the configuration in the vicinity of the line LN is formed. Among these figures, FIG. 14A to FIG. 14D show steps included in the process PR1 for forming the circuit layer 11.

That is, first, the inorganic insulating layer 31 is formed on the substrate 10, the line LN is formed on the inorganic insulating layer 31, and the inorganic insulating layer 32 covering the line LN is formed as shown in FIG. 14A Next, as shown in FIG. 14B, etching removes the inorganic insulating layer 32 between adjacent lines LN.

Thereafter, as shown in FIG. 14C, the inorganic insulating layer 33 covering the inorganic insulating layers 31 and 32 is formed. Next, as shown in FIG. 14D, etching removes the inorganic insulating layers 31 and 33 between adjacent lines LN.

In the subsequent processes PR3, PR5, and PR13, the waterproof layer 13, the rib layer 5, and the sealing layer SE2 are formed as shown in FIG. 14E. Further, as shown in FIG. 14F, etching removes the waterproof layer 13, the rib layer 5, and the sealing layer SE2 between adjacent lines LN in the process PR14. These processes form the second area A2.

In the subsequent process PR15, the sealing layer SE2 above the line LN is removed as shown in FIG. 14G. These processes yield the configuration shown in FIG. 9.

FIG. 15 is a schematic plan view showing the vicinity of the terminal portion T before being cut along the cut line CL2. The line LN crosses the cut line CL2 and is connected to the conductive layer of the mother substrate MB. This configuration can suppress electrostatic breakdown in the manufacturing process resulting from the line LN and elements connected thereto in the display area DA and the surrounding area SA.

In the example of FIG. 15, the second area A2 crosses the cut line CL2 and extends longer in the Y-direction. In the process PR19, the line LN and the second area A2 are cut along the cut line CL2. This cutting yields the configuration shown in FIG. 7.

The present embodiment can improve the yield of the display device DSP. That is, the inorganic insulating layers 31, 32, and 33 that are provided on the cut line CL2 may be stripped from the substrate 10 at the time of cutting. In particular, use of laser cut may improve the possibility of the stripping of the inorganic insulating layers 31, 32, and 33 due to thermal stress applied to them. In one example, strip easily occurs between the gate insulating film GI1 formed of TEOS and the interlayer insulating film ILD1 formed of a silicon nitride in the layer configuration shown in FIG. 6.

In contrast, in the present embodiment, the inorganic insulating layers 31, 32, and 33 are removed in the first area A1 along the cut line CL2. This configuration can suppress the stripping.

The first area A1 may function progressing of cracks in the inorganic insulating layers 31, 32, and 33. That is, even if cracks form in the inorganic insulating layers 31, 32, and 33 outside the cut line CL2, the first areas A1 can stop progression of the cracks toward the display area DA.

In the present embodiment, the inorganic insulating layers 31, 32, and 33 are removed in the second area A2 between the lines LN in the vicinity of the terminal portion T as well. This configuration can suppress the stripping in the same manner as the first area A1. In contrast, the inorganic insulating layers 31, 32, and 33 around the line LN remain. This configuration can protect the line LN.

In the present embodiment, the rib layer 5, the waterproof layer 13, and the sealing layer SE2 each formed of inorganic insulating materials are removed in the first area A1 and the second area A2 as well. This configuration can suppress stripping of these rib layer 5, waterproof layer 13, and sealing layer SE2 as well.

In cases where the inorganic insulating layers 31, 32, and 33 are removed in the first area A1, a deep trench portion is formed along the cut line CL2. This trench portion may result in application failure of resists formed in various steps. In view of this point, the present embodiment has the organic insulating layers 12a and 34a provided in the first area A1. Thus, the trench portion is filled, and application failure of the resists can be suppressed. As described above, the organic insulating layers 12a and 34a can also function as dam portions for retaining the resin layer RS2.

In the manufacturing process of the display device DSP, the etching in the process PR14 removes the terminal portion T, the rib layer 5, the waterproof layer 13, and the sealing layer SE2 in the first area A1 and the second area A2. In this manner, aligning the layer configurations of removal targets in the terminal portion T, the first area A1, and the second area A2 at the time of etching can suppress unintended erosion of underlying elements.

The stacked films FL1, FL2, and FL3 that are formed by vapor deposition may have lower adhesion to the base. Thus, the stacked films FL1, FL2, and FL3 and the sealing layers SE11, SE12, and SE13 covering these films may be stripped during manufacturing of the display device DSP. Such stripping tends to occur when the stacked films FL1, FL2, and FL3 are continuously formed over a wide area. In the display area DA, the partition 6A divides the stacked films FL1, FL2, and FL3 into smaller pieces. This configuration can suppress the stripping.

The present embodiment has the partitions 6B, 6C, and 6D provided in the area outside the display area DA. This configuration causes the stacked films FL1, FL2, and FL3 to be divided into smaller pieces in this area as well, suppressing the stripping.

The partition 6D that remains in the first area A1 until the process PR19 may hamper smooth cutting along the cut line CL2. In view of this point, the partition 6D in the present embodiment is removed in the process PR11. Thus, cutting along the cut line CL2 is not affected by the partition 6D in the first area A1.

Various desirable effects can be obtained from the present embodiment in addition to the above-described effects.

The following will disclose the second to seventh embodiments. Among these embodiments, the second to fifth embodiments correspond to modified examples applicable in the manufacturing process of the configuration in the vicinity of the line LN. Further, the sixth and seven embodiments correspond to modified examples applicable to the cross-sectional configuration including the first area A1.

The following will describe the second embodiment, which is a modified example of the present embodiment.

### Second Embodiment

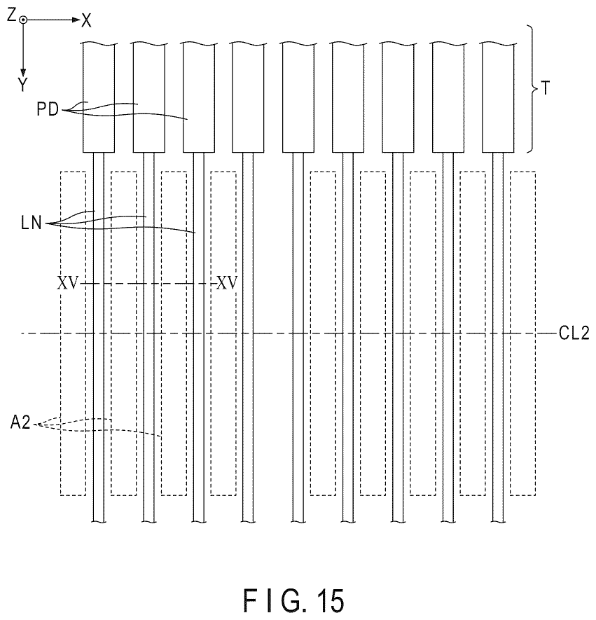

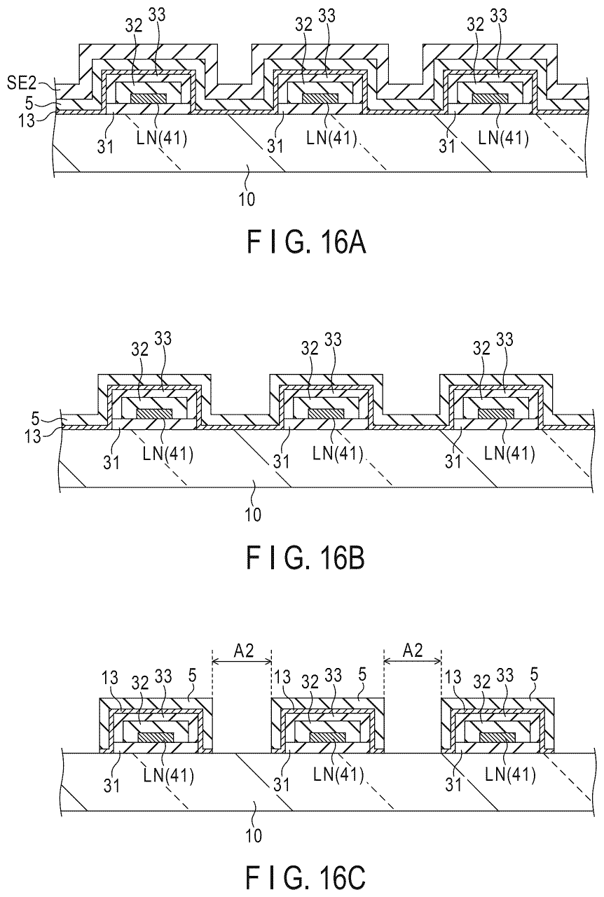

FIG. 16A to FIG. 16C are schematic cross-sectional views showing manufacturing processes of the display device DSP according to the second embodiment. In the same manner as FIG. 14A to FIG. 14G, these figures show the state where the configuration in the vicinity of the line LN is formed.

In the same manner as FIG. 14E, FIG. 16A has the line LN provided on the inorganic insulating layer 31, and the line LN covered with the inorganic insulating layers 32 and 33, the waterproof layer 13, the rib layer 5, and the sealing layer SE2.

As shown in FIG. 16B, in the present embodiment, etching removes the entire sealing layer SE2 above the line LN and the area between adjacent lines LN. Thereafter, as shown in FIG. 16C, etching removes the waterproof layer 13 and the rib layer 5 between adjacent lines LN. These processes form the second area A2.

The manufacturing method of the present embodiment can also yield the configuration shown in FIG. 9.

### Third Embodiment

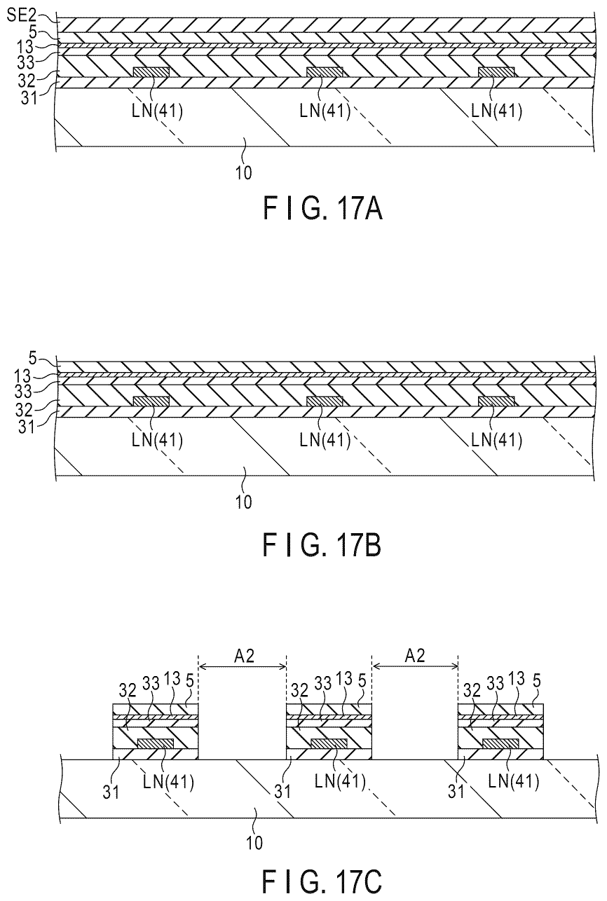

FIG. 17A to FIG. 17C are schematic cross-sectional views showing manufacturing processes of the display device DSP according to the third embodiment. In the same manner as FIG. 14A to FIG. 14G, these figures show the state where the configuration in the vicinity of the line LN is formed.

In the present embodiment, the inorganic insulating layer 31, the line LN, the inorganic insulating layer 32, the inorganic insulating layer 33, the waterproof layer 13, the rib layer 5, and the sealing layer SE2 are stacked in this order as shown in FIG. 17A. The present embodiment differs from the examples of FIG. 14A to FIG. 14G in the point that the inorganic insulating layers 31, 32, and 33 between adjacent lines LN are not removed in this state.

Next, as shown in FIG. 17B, etching removes the sealing layer SE2. Further, as shown in FIG. 17C, etching simultaneously removes the inorganic insulating layers 31, 32, and 33, the waterproof layer 13, and the rib layer 5 between adjacent lines LN. These processes form the second area A2.

The manufacturing method of the present embodiment can yield the configuration in which the inorganic insulating layers 31, 32, and 33, the waterproof layer 13, and the rib layer 5 cover the line LN and these layers are removed in the second area A2.

### Fourth Embodiment

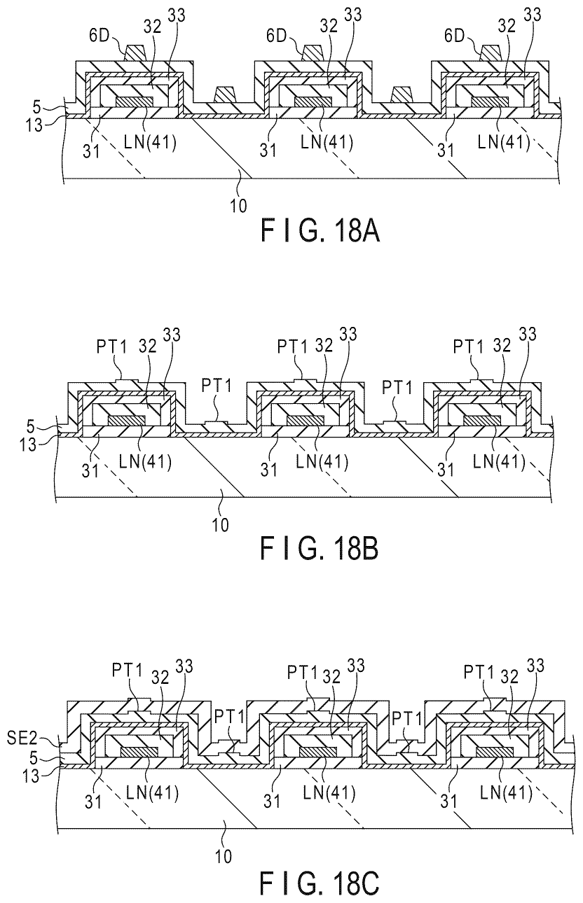

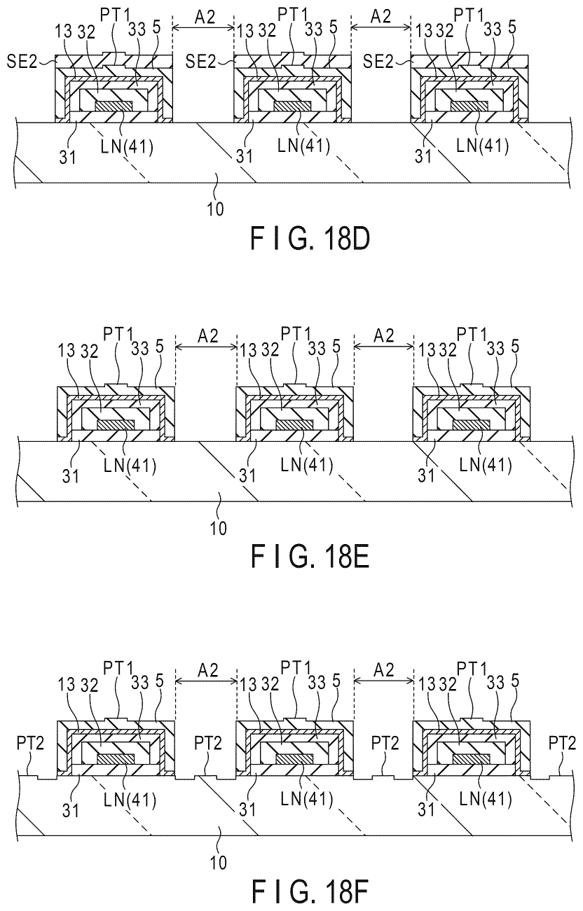

FIG. 18A to FIG. 18E are schematic cross-sectional views showing manufacturing processes of the display device DSP according to the fourth embodiment. In the same manner as FIG. 14A to FIG. 14G, these figures show the state where the configuration in the vicinity of the line LN is formed.

In the same manner as FIG. 14E, FIG. 18A has the line LN provided on the inorganic insulating layer 31, and the line LN covered with the inorganic insulating layers 32 and 33, the waterproof layer 13, and the rib layer 5. At this time, the sealing layer SE2 is not provided.

Further, the present embodiment has the partition 6D provided on the rib layer 5 in the vicinity of the line LN as well. The arrangement mode of the partition 6D is not particularly limited. In one example, the partition 6D may be provided above the line LN and the area between the adjacent lines LN as shown in FIG. 18A.

The partition 6D in the vicinity of the line LN is removed in the process PR11. As described above, this etching may include wet etching or dry etching on each layer of the partition 6D. This dry etching may slightly erode the rib layer 5 as well. This erosion results in the formation of a protrusion portion PT1 corresponding to the shape of the partition 6D on the upper surface of the rib layer 5 as shown in FIG. 18B.

Thereafter, as shown in FIG. 18C, the sealing layer SE2 is formed. Further, as shown in FIG. 18D, etching removes the waterproof layer 13, the rib layer 5, and the sealing layer SE2 between adjacent lines LN. Further, etching removes the sealing layer SE2 above the line LN as shown in FIG. 18E. The protrusion portion PT1 may remain even in this state.

Providing the partition 6D in the vicinity of the line LN as in the present embodiment can suppress the stripping of the stacked films FL1, FL2, and FL3 and the sealing layers SE11, SE12, and SE13 formed in the vicinity of the line LN in the processes PR8, PR9, and PR10.

FIG. 18F is a schematic cross-sectional view of a modified example of the present embodiment. As described above in the first embodiment, the substrate 10 may be a resin film. For example, a material for the resin material may be a polyimide.

When the substrate 10 is formed of a resin film, traces of the partitions 6D may remain on the upper surface of the substrate 10 as shown in a protrusions PT2 shown in FIG. 18F. That is, removing the waterproof layer 13, the rib layer 5, and the sealing layer SE2 between adjacent lines LN by etching in this state shown in FIG. 18C may remove the upper surface of the substrate 10 by the etching. This erosion may result in the formation of the protrusion portion PT2 corresponding to the shape of the protrusion portion PT1 on the upper surface of the substrate 10.

### Fifth Embodiment

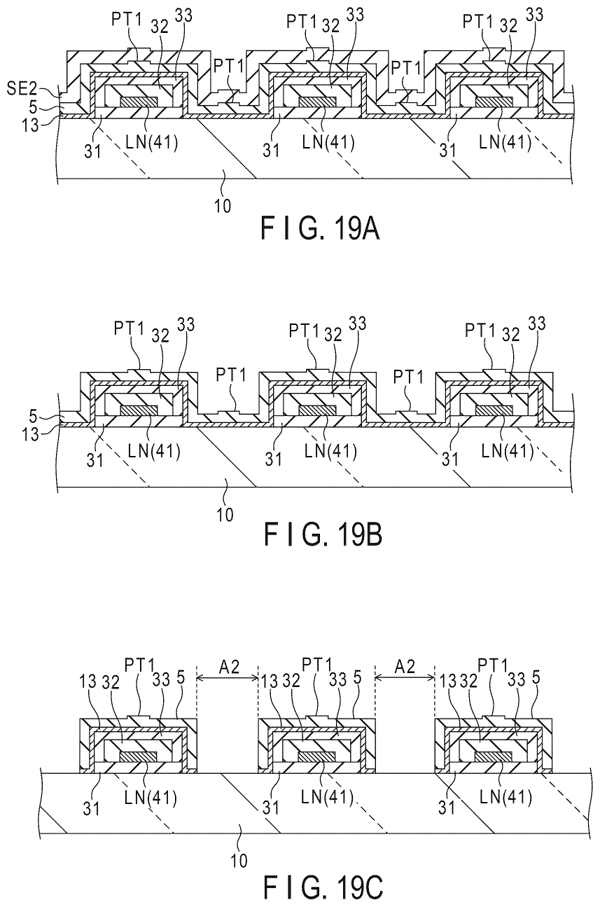

FIG. 19A to FIG. 19C are schematic cross-sectional views showing manufacturing processes of the display device DSP according to the fifth embodiment. In the same manner as FIG. 14A to FIG. 14G, these figures show the state where the configuration in the vicinity of the line LN is formed.

The configuration in FIG. 19A is the same as FIG. 18C. Thereafter, as shown in FIG. 19B, in the present embodiment, etching removes the entire sealing layer SE2 above the line LN and the area between adjacent lines LN. Thereafter, as shown in FIG. 19C, etching removes the waterproof layer 13 and the rib layer 5 between adjacent lines LN. These processes form the second area A2.

The manufacturing method of the present embodiment can achieve the same effects as those of the fourth embodiment.

### Sixth Embodiment

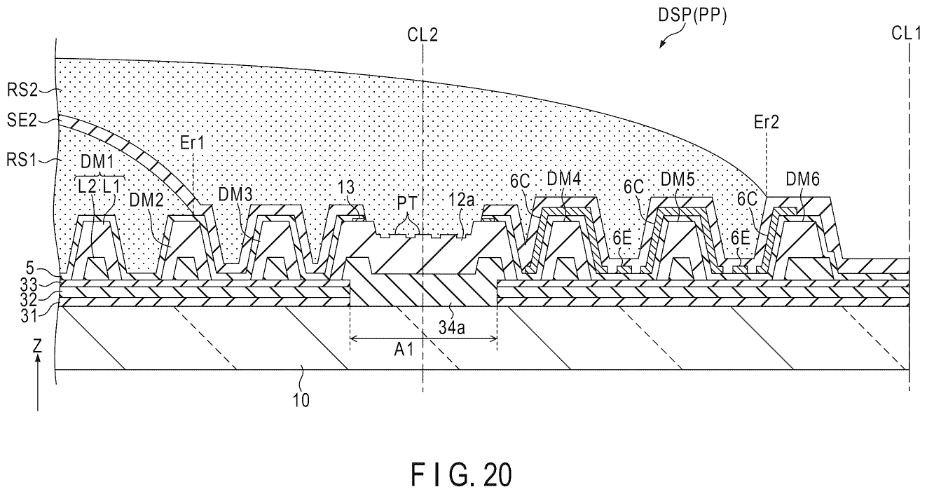

FIG. 20 is a schematic cross-sectional view of the display device DSP according to the sixth embodiment. This figure shows the vicinity of the first area A1 in the state where cutting along the cut line CL2 has not been conducted (in the panel portions PP).

In the present embodiment, the dam portion DM4 is provided between the cut lines CL1 and CL2. Further, in the example of FIG. 20, dam portions DM5 and DM6 having the same configuration as the dam portion DM4 are also provided between the cut lines CL1 and CL2.

The partition 6C covering the dam portions DM4, DM5, and DM6 is provided above the rib layer 5. Further, partitions 6E are provided in valley portions between the dam portions DM4 and DM5 and between the dam portions DM5 and DM6. In the same manner as the partitions 6A, 6B, 6C, and 6D, the partition 6E comprises the lower portion 61 (the bottom layer 63 and the stem layer 64) and the upper portion 62. The end portion of the partition 6E has an overhang shape in which the upper portion 62 protrudes relative to the side surface of the lower portion 61.

The dam portions DM4, DM5, and DM6 retain the resin layer RS2 before curing. In the example of FIG. 20, the end portion Er2 of the resin layer RS2 is located in the vicinity of the dam portion DM6. This configuration causes the cut line CL2 to overlap the resin layer RS2. Cutting along the cut line CL2 cuts the resin layer RS2 as well.

The configuration of the present embodiment can reduce the number of the dam portions that are located inside the cut line CL2. This configuration can enable the design of the display device DSP with the surrounding area SA having a smaller width.

### Seventh Embodiment

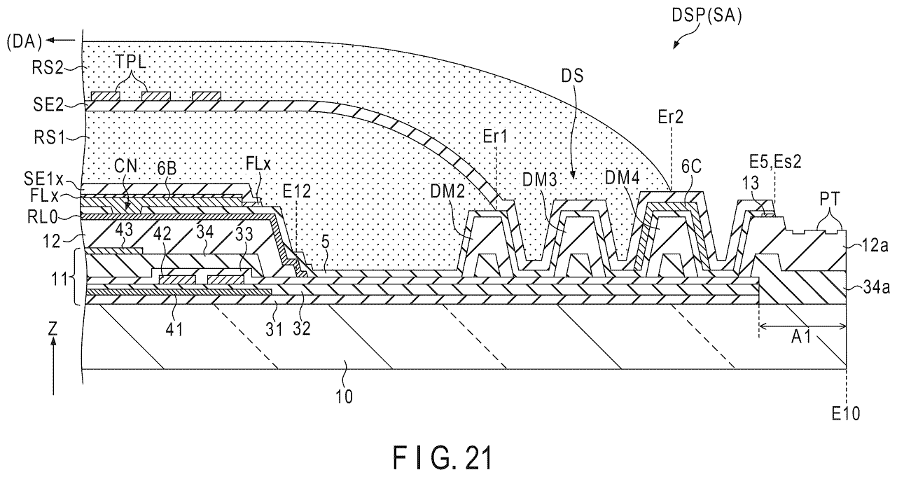

FIG. 21 is a schematic cross-sectional view of the display device DSP according to the seventh embodiment. The figure shows the cross section of the part corresponding to the one shown in FIG. 5.

The configuration shown in FIG. 21 differs from the configuration of FIG. 5 in omitting the dam portion DM1. In the same manner as the sixth embodiment, this configuration also can reduce the number of the dam portions provided in the surrounding area SA and enable the design of the display device DSP with the surrounding area SA having a smaller width.

The display device DSP and its manufacturing method can encompass various examples in addition to the first to seventh embodiments.

For example, each embodiment shows as an example the configuration in which all of the inorganic insulating layers 31, 32, and 33 are removed in the first area A1 and the second area A2. Any of the inorganic insulating layers included in the circuit layer 11 may not be removed in the first area A1 and the second area A2. Even in this case, removing a least one of the plurality of inorganic insulating layers from the first area A1 and the second area A2 can reduce the risk of stripping after the cutting.

The configuration of the line LN disclosed in each embodiment is applicable to various lines provided for purposes other than suppressing electrostatic breakdown. Examples of the various lines include lines connected to a test pad provided outside the cut line CL2.

All of the display devices and manufacturing methods thereof that can be implemented by a person of ordinary skill in the art through arbitrary design changes to the display device and manufacturing method thereof disclosed above as each embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A display device, comprising:
a substrate;
a circuit layer provided above the substrate and including a plurality of conductive layers and a plurality of inorganic insulating layers that constitute a pixel circuit configured to drive a pixel in a display area;
a first organic insulating layer provided above the circuit layer;
a rib layer provided above the first organic insulating layer and having a pixel aperture in the pixel;
a display element overlapping the pixel aperture; and
a partition provided above the rib layer and having an overhang shape surrounding the display element, wherein
a first area in which at least one of the plurality of inorganic insulating layers are removed is formed along an end portion of the substrate.

2. The display device of claim 1, wherein
all of the plurality of inorganic insulating layers are removed in the first area.

3. The display device of claim 1, wherein
the first organic insulating layer is provided in the first area.

4. The display device of claim 3, wherein
the circuit layer includes a second organic insulating layer located above the plurality of inorganic insulating layers,
the first organic insulating layer contacts an upper surface of the second organic insulating layer in the first area, and
the second organic insulating layer contacts an upper surface of the substrate in the first area.

5. The display device of claim 3, wherein
an upper surface of the first organic insulating layer in the first area has a protrusion portion.

6. The display device of claim 3, further comprising:
a waterproof layer formed of an inorganic insulating material and located between the first organic insulating layer and the display element in the display area, wherein
the waterproof layer covers at least part of an upper surface of the first organic insulating layer in the first area.

7. The display device of claim 1, wherein
the rib layer is formed of an inorganic insulating material, and
the rib layer is removed in at least part of the first area.

8. The display device of claim 1, further comprising:
a dam structure surrounding the display area; and
a first resin layer covering the display area and having an end portion overlapping the dam structure in plan view, wherein
the first area is located outside the dam structure.

9. The display device of claim 8, further comprising:
a sealing layer formed of an inorganic insulating material and covering the first resin layer and the dam structure, wherein
the sealing layer is removed in the first area.

10. The display device of claim 9, further comprising:
a second resin layer covering the sealing layer, wherein
an end portion of the second resin layer is located between the end portion of the first resin layer and the first area.

11. The display device of claim 1, further comprising:
a terminal portion configured to supply signals that drive the pixel, wherein
the plurality of conductive layers include a plurality of lines provided between the terminal portion and the end portion of the substrate, and
at least one of the plurality of inorganic insulating layers is removed in a second area between the plurality of lines.

12. The display device of claim 11, wherein
each of the plurality of lines is covered with the rib layer and at least one of the plurality of inorganic insulating layers.

13. The display device of claim 12, further comprising:
a waterproof layer formed of an inorganic insulating material and located between the first organic insulating layer and the display element in the display area, wherein
the waterproof layer is provided between the plurality of inorganic insulating layers and the rib layer in the second area.

14. A manufacturing method of a display device comprising:
forming above a substrate a circuit layer including a plurality of conductive layers and a plurality of inorganic insulating layers that constitute a pixel circuit configured to drive a pixel in a display area;
removing at least one of the plurality of inorganic insulating layers in a first area along a cut line for cutting out a panel portion including the display area from the substrate;
forming a first organic insulating layer above the circuit layer;
forming a rib layer provided above the first organic insulating layer and having a pixel aperture in the pixel;
forming above the rib layer a partition having an overhang shape surrounding the pixel aperture;
forming a display element overlapping the pixel aperture; and
cutting the substrate along the cut line.

15. The manufacturing method of claim 14, wherein
the removing includes removing all of the plurality of inorganic insulating layers in the first area.

16. The manufacturing method of claim 15, further comprising:
after removing all of the plurality of inorganic insulating layers in the first area, forming a second organic insulating layer contacting an upper surface of the substrate in the first area.

17. The manufacturing method of claim 16, wherein
the first organic insulating layer is formed to cover the second organic insulating layer in the first area.

18. The manufacturing method of claim 14, further comprising:
forming a dam structure surrounding the display area; and
forming a first resin layer covering the display area and having an end portion overlapping the dam structure in plan view, wherein
the first area is located outside the dam structure.

19. The manufacturing method of claim 18, further comprising:
forming a sealing layer of an inorganic insulating material, the sealing layer covering the first resin layer and the dam structure; and
removing the sealing layer in the first area.

20. The manufacturing method of claim 14, wherein
a plurality of conductive layers include a plurality of lines provided between a terminal portion configured to receive signals driving the pixel and an end portion of the substrate, and
the method further comprises:
removing at least one of the plurality of inorganic insulating layers in a second area between the plurality of lines.
